(19) United States
(12) Patent Application Publication
(10) Pub. No.: US 2017/0218494 A1
(43) Pub. Date: Aug. 3, 2017

(54) PLASMA COATING OF THERMOELECTRIC ACTIVE MATERIAL WITH NICKEL AND TIN

(71) Applicants: Jens BUSSE, Bochum (DE); Sascha HOCH, Bochum (DE); Magdalena KERN, Alzenau (DE); Mareike GIESSELER, Maintal (DE); Thorsten SCHULTZ, Hassenroth (DE); Patrik STENNER, Hanau (DE)

(72) Inventors: Jens BUSSE, Bochum (DE); Sascha HOCH, Bochum (DE); Magdalena KERN, Alzenau (DE); Mareike GIESSELER, Maintal (DE); Thorsten SCHULTZ, Hassenroth (DE); Patrik STENNER, Hanau (DE)

(73) Assignee: Evonik Degussa GmbH, Essen (DE)

(21) Appl. No.: 15/515,172

(22) PCT Filed: Sep. 29, 2015
(86) PCT No.: PCT/EP2015/072427

§ 371 Date: Mar. 29, 2017

(30) Foreign Application Priority Data
Sep. 30, 2014 (DE) 10 2014 219 756.2

(51) Int. Cl. C23C 4/08; H01L 35/08; H01L 35/34; C23C 4/134

(52) U.S. Cl. CPC C23C 4/08; C23C 4/134; H01L 35/08; H01L 35/34

(57) ABSTRACT

The invention relates to a method for producing a thermoelement for a thermoelectric component, in which method: with the aid of a plasma flame, a diffusion barrier made of nickel is applied to a thermoelectric active material; or, with the aid of a plasma flame, a contact-facilitating layer made of tin is applied to a diffusion barrier made of nickel. The invention also relates to a thermoelectric component comprising thermoelements which are produced correspondingly. The aim of the invention is to further develop the conventional plasma spraying technique such that it can be used to produce thermoelements on an industrial scale. To achieve this aim, nickel particles or tin particles are used, which particles conform to a particular specification with regard to their sphericity.

The invention relates to a method for producing a thermoleg for a thermoelectric component, in which a diffusion barrier of nickel is applied to a thermoelectric active material with the aid of a plasma flame; and in which a contact maker layer of tin is applied to a diffusion barrier of nickel with the aid of a plasma flame. The invention also relates to a thermoelectric component with thermolegs that are correspondingly produced.

A thermoelectric component is an energy transducer which converts thermal energy to electrical energy, exploiting the thermoelectric effect described by Peltier and Seebeck. Since the thermoelectric effect is reversible, every thermoelectric component can also be used for the conversion of electrical energy into thermal energy: so-called Peltier elements serve for cooling or heating objects while taking up electrical power. Peltier elements are therefore also regarded as thermoelectric components. Thermoelectric components, which serve for conversion of thermal energy to electrical energy, are often referred to as thermoelectric generators (TEGs).

Examples of and introductions to thermoelectric components can be found in:
Thermoelectrics Goes Automotive, D. Jänsch (ed.), expert verlag GmbH, 2011, ISBN 978-3-8169-3064-8;
JP2006032850A;
EP0773592A2;
U.S. Pat. No. 6,872,87961;
US20050112872A1;
JP2004265988A.

Industrially produced thermoelectric components comprise at least one thermocouple of thermoelectric active material, formed from two thermolegs, and a substrate which bears and/or surrounds and electrically insulates the thermocouple from the outside.

The prior art describes a multitude of thermoelectric active materials. Examples of suitable alloys for commercial use include those from the class of the semiconductive bismuth tellurides (especially with additional components of selenium and/or antimony), from which—with respective p-conductive doping and n-conductive doping—it is possible to form a thermocouple.

Further thermoelectrically active substance classes are: semi-Heusler materials, various silicides (especially magnesium, iron), various skutterudites, various tellurides (lead, tin, lanthanum, antimony, silver), various antimonides (zinc, cerium, iron, ytterbium, manganese, cobalt, bismuth; some are also referred to as Zintl phases), TAGS, silicon germanides, clathrates (especially based on germanium). As well as these semiconductor materials, thermoelectric components can also be produced from combinations of most standard metals, as is the case, for example, for conventional thermocouples for temperature measurement, e.g. Ni—CrNi. However, the figures of merit (thermoelectric “efficiencies”) thus achievable are much lower than in the semiconductor materials mentioned.

In thermoelectric components, the thermolegs consisting of active material must be brought into electrical contact with metallic conductors (known as “contact bridges”) to form a thermocouple, while it is necessary to ensure a very low electrical resistance through the joint. At the same time atoms from the metallic conductor and/or the solders and soldering aids used for the electrical connection, or substances that are used in other joining methods, must be prevented from diffusing into the active materials, which could lead to undesired changes of their thermoelectric properties. This can be prevented by applying a diffusion barrier to the thermoelectric active material. A classic suitable barrier material for many of the active materials currently used is nickel.

When applying the diffusion barrier to the thermoelectric active material, the following aspects must generally be considered:
creating a diffusion barrier that is effective and at the same time as thin as possible with suitable homogeneity, impermeability and layer thickness;
high electrical volume resistance of the applied layer(s), and also low electrical transfer resistances in all of the contact zones of different layers;
low investment and operating costs for the coating, in order to keep down the production costs of the thermoelectric component, because only then can it be used cost-effectively;
the coating method must be suitable for mass production, it must be scalable and be easily manageable, it must provide consistent quality and high throughputs and must be easily adaptable to changed geometries and/or materials;
it must provide a layer structure that is uniform and can be controlled well;
it must provide uniform, good adherence on different thermoelectric active materials;
there may only be small losses of coating material;
the toxicity of finely divided metals (especially nickel) must be managed;
the method must provide a locally definable layer structure, to be specific only on the surface of the active material that is to be coated, generally in the region of the later contact point with respect to the conductor; deposits at points that are not desired or are superfluous should be avoided, and the formation of undesired electrical connections between neighbouring thermoelectric legs is undesired;
the method should be robust when there are quality fluctuations of the coating materials used and of the active materials to be coated;
the method should allow an integral transition;
finally, the method should ensure good mechanical and electrical bondability to commonly used electrical conductor materials, such as copper, silver, aluminium, tin or gold.

In actual industrial operations, the application of the diffusion barrier to the active material takes place by nickel sputtering, galvanic coating, flame spraying or CVD/PVD coating.

The conventional coating technologies have a variety of disadvantages:

Nickel sputtering is a laborious and expensive method that requires a high vacuum and a high-purity nickel target. It offers only low throughputs because of the high-vacuum chamber and the limited nickel removal rate from the target. Another objection here is high nickel consumption because of inefficiency, since the deposition takes place on virtually all of the surfaces of the vacuum chamber. Finally, the energy consumption is immense. The same also applies in principle to CVD/PVD technology.

Galvanic coating achieves only limited adherence on semiconductors. It also has very high demands for cleaning the active surface and cleanness in general. The aggressive galvanic baths may attack semiconductors and other components of the thermoelectric element or else the counterelectrode, and furthermore they are highly toxic and environmentally hazardous.

Another point of criticism is that a uniform layer structure requires a homogeneous current density distribution. This is scarcely achievable in practice on account of often inhomogeneous semiconductors and superficial oxide films/contaminants on the active materials.

With simultaneous coating of a number of thermoelectric legs, different internal resistances and contact resistances of the legs likewise result in highly inhomogeneous current distribution on the legs. For this reason, simultaneous coating of n and p legs is generally not possible.

The electrical contacting of a multiplicity of thermoelectric legs while at the same time avoiding contact of the contacting zone with liquid galvanic baths is highly complex in terms of structural design.

On account of the aggressive baths, the counterelectrodes are subject to high wear, and are therefore expensive. Toxic and/or corrosive substances can also form on them.

Finally, the composition of the bath changes during the galvanic coating, which makes uniform deposition and control of the process more difficult.

Flame spraying also does not provide a better alternative. Therefore, a layer structure that is inhomogeneous and difficult to control and limited local controllability of the deposition are typical here. This is so because the flame must achieve a certain minimum size to be able to heat up nickel powder sufficiently. For this reason, flame spraying is not suitable for filigree structures of less than a few millimetres in diameter.

Flame-sprayed barrier layers often have high porosity and consequently inadequate impermeability.

Furthermore, in the case of flame spraying there is a noticeable sandblasting effect, which leads to removal of the active material.

The adherence of flame-sprayed barrier layers on semiconductor active materials is often inadequate, as a result of oxide formation on nickel and semiconductors due to oxidizing agents in the flame. This leads to a high electrical resistance at the contact point of the thermoleg, causing the efficiency of the thermoelectric module to fall.

WO2013/144106A1 discloses the application of a diffusion barrier of nickel to thermoelectric active material by pressing and sintering on a disc punched out from a foil. This document also mentions powder plasma spraying in connection with the application of barrier material, without however going into details.

A disadvantage of application by pressing and sintering is that the entire thermoelectric leg has to be brought to the sintering temperature of the nickel. This may be too high for many thermoelectric semiconductors. The use of a foil also leads to layers that are thicker than is necessary for the impermeability of the barrier. The sintering must also take place under mechanical pressure and takes a relatively long time, which limits throughput and machine utilization.

WO2008/077608A2 discloses a method for spraying a strip conductor onto a substrate in which a metal powder is applied to the substrate with the aid of a cold plasma under atmospheric conditions and forms the strip conductor there. This document specifically mentions tin and copper as coating material. In the exemplary embodiment, tin powder with a particle size in the range from 1 μm to 100 μm particle diameter is used. No further details are given about the nature of the powder. According to this document, pretreatment of the substrate to be coated is not required. Thermoelectric active material is not coated.

CH401186 describes a method for producing thermolegs for a thermoelectric component in which a diffusion barrier of nickel is applied to a thermoelectric active material with the aid of a hot plasma flame. Cleaning of oxidized material is recommended as a pretreatment before the coating, in particular by sandblasting in order to roughen the surface and improve the adherence of the diffusion barrier. This document similarly describes how a second layer, for example of copper or iron, may be applied to the diffusion barrier, in order to facilitate soldering of an electrical contact onto the thermoleg. However, here, too, no specific details of the nature of the powder are given.

Attempts by the applicant to spray powdered nickel onto thermoelectric active material by plasma spraying technology available on the market in order to form a diffusion barrier on the material failed.

The inventors therefore found themselves faced with the object of developing the conventional plasma spraying technology in such a way as to allow thermolegs to be produced on an industrial scale.

This object was achieved by using nickel particles that have an average sphericity of greater than 0.74.

This is so because the inventors have realized that a key to the successful production of a diffusion barrier of nickel lies in managing the feeding of the particles into the plasma flame. In order to deposit a nickel layer with the properties described above on thermoelectric active material, the nickel powder clearly has to be fed to the plasma flame in a particular manner that differs from the feeding of other metal powders. Simply using nickel powder in place of metal powders previously used was unsuccessful.

According to the invention, a nickel powder of which the particles have a particular sphericity is used.

The “sphericity” Ψ is a measure of the degree of the spherical shape of an irregularly shaped body. It is mathematically defined by the ratio of the surface of a sphere that has the same volume V as the body to the surface A of the body:

$$Ψ = \frac{{{π}^{\frac{1}{3}} ( 6 V )}^{\frac{2}{3}}}{A}$$

The sphericity Ψ can assume values between zero and one. An ideal sphere has a sphericity of 1. The more irregularly the body is shaped, the lower its sphericity: A cube with three edges of equal length thus has for instance a sphericity of approximately 0.8. A comparatively acute tetrahedron has a sphericity of only 0.67. On the other hand, an indeed partially round cylinder has a higher sphericity, of 0.87.

The mathematical concept of sphericity accordingly describes the roundness of the particles and can be used as an indicator of the flow behaviour of powder. Since a powder consists of a multiplicity of individual particles of different individual sphericities, it makes sense to assign the powder a statistical overall sphericity value. For this purpose, the sphericity of individual particles is determined and the mean value formed from them. Reference is then made to the mean sphericity SM of a particle fill.

Particle technology has developed various measuring methods that allow determination of the sphericity of a powder.

Image-processing methods allow the shape to be recorded and can calculate the sphericity from the shape and size. There are dynamic and static image-processing systems. An example of a dynamic system is QicPic from the company Sympatec. Static systems are contained in optical microscopes or scanning electron microscopes (SEM) and evaluate individual images.

QicPic from the company Sympatec GmbH determines the sphericity on the basis of the ratio of the circumference of the circle of the same area P_{EQPC} to the actual circumference Pᵣₑₐₗ. It uses a two-dimensional approach that departs from the mathematically ideal three-dimensional approach but nevertheless offers a good approximation.

By this measuring method, the mean sphericity of the powders used was determined. Tests show that a nickel powder with a mean sphericity SM of greater than 0.74 exhibits a flow behaviour that allows the nickel particles to be fed continuously to a plasma flame, and so in this way a reliably impermeable diffusion barrier can be created. This is so because an interrupted particle stream must be avoided as far as possible, since otherwise the homogeneity necessary for this intended use and the thickness of the layer cannot be maintained. The mean sphericity is ideally 0.79.

The subject matter of the invention is consequently a method for producing a thermoleg for a thermoelectric component in which a diffusion barrier of nickel is applied to a thermoelectric active material with the aid of a plasma flame in which nickel particles that have a mean sphericity SM of greater than 0.74 are fed to the plasma flame.

Particularly preferred is a mean sphericity SM in the range from 0.78 to 0.8, in which the optimum value of 0.79 lies.

These values relate to measurements with QicPic from the company Sympatec GmbH.

Apart from the sphericity, the particle size distribution of the nickel powder used also has a decisive effect on the processability of the powder, and consequently on the coating quality achieved. A preferred development of the invention therefore envisages using nickel particles that have the following specification with regard to their particle size distribution:
D₅₀ of 0.6 μm to 25 μm, with 4 μm to 7 μm being preferred.

The particle size distribution D₅₀ should be understood as meaning that 50% of the particles used have an equivalent diameter in the range claimed. The equivalent diameter is the diameter of a sphere that has the same volume as the irregular particle. A measuring method that is suitable for nickel powder is that of static light diffusion. A suitable device is the Retsch Horiba LA-950.

A suitable nickel powder of which the particles have both the required sphericity and the advantageous particle size distributions is obtained by the particles being spray-dried and screened. In the spray drying, liquid nickel is atomized in a gas stream, and so the liquid nickel drops have a tendency to adopt a spherical shape to reduce their surface tension. Solidified (dried) in the gas stream, the particles are given their spherical shape, and so they achieve a high degree of sphericity.

These particles must not be ground any more after that, since the grinding process causes the round particles to be flattened again and/or to break up with sharp edges. Thus, ground powder with an identical D₅₀ value has a mean sphericity of 0.47, and therefore cannot be used according to the invention.

For this reason, the desired particle size distribution must be set by screening. Screening is a classifying method in which the particles of the desired size are selected from the spray-dried coarse powder. In air classification, the fine fraction is separated by the small particles sedimenting more slowly in the gas stream.

Since the spray drying is not followed by a working step that brings about a reduction of the particle size distribution, the nickel particles that can be used are in principle already obtained after the spray drying; they just have to be selected from the total amount of spray-dried nickel powder. For this reason, the spray drying of the nickel particles is particularly important.

Apart from the nature of the particle powder, the process parameters of the plasma coating installation are also significant:

Plasma coating installations are commercially available. Their main component is a nozzle in which a carrier gas stream of an ionizable gas flows in. The metal powder is also fed into the nozzle, and in it is dispersed in the carrier gas stream. The carrier gas is passed through an ionizing zone, in which a high electrical voltage discharges. For this, the nozzle specifically has an anode and a cathode, between which the voltage undergoes a spark discharge. The carrier gas flows through the region where the discharge occurs and is thereby ionized, that is to say imparted with an ionic charge of the same sign. The ionized carrier gas with the particles dispersed in it leaves the nozzle as a plasma stream and impinges on the surface to be coated of the thermoelectric active material. The nickel particles are thus deposited on the active material

This is so because in the plasma flame the surface of the metal particles is activated in such a way that, when they impinge on the target surface, they adhere to it and can form a layer. It is possibly even the case that the coating material sinters with the substrate lying thereunder, that is to say the active material or the first coating gas.

Nitrogen (N₂) or hydrogen (H₂) or mixtures thereof is/are preferably used as the ionizable carrier gas. Forming gas that is a mixture of 95% by volume nitrogen and 5% by volume hydrogen is preferably used as the carrier gas. The hydrogen fraction gives the plasma stream a reducing effect, which allows the removal of undesired oxide films on the thermoelectric active material. As a result, the thermal and electrical resistance of the contact point falls, and so the efficiency of the later thermoelectric component is increased. The high nitrogen fraction suppresses new oxidation and lowers the risk of explosion.

A pulsed DC voltage of between 10 kV and 50 kV with a pulse frequency of between 15 kHz and 25 kHz is preferably used for the ionization.

However, the efficiency of the process is increased if the ionization and dispersion take place simultaneously in the nozzle. Nevertheless, commercially available plasma nozzles are constructed in such a way that the ionization of the carrier gas takes place first and then, directly after that, that is to say before leaving the nozzle, the powder is dispersed in the already ionized carrier gas.

The temperature of the plasma flame should be set to a value below 3000 K, in order that the thermoelectric active material is not damaged. The plasma temperature is dependent on the process gas, the power output and the pressure. However, the temperature on the substrate is decisive. Here, the melting point of the semiconductor must not be exceeded. The temperature on the substrate is also influenced by the travelling speed of the plasma pin. A sufficient plasma temperature must be chosen to activate the nickel superficially, and a temperature on the substrate without destroying it.

The plasma coating specifically takes place as follows:
a) the carrier gas is fed into the nozzle with a volumetric flow of 10 Nl/min to 60 Nl/min, with 30 Nl/min being preferred;
b) the carrier gas is ionized in the nozzle by being passed through an electrical discharge induced by the electrical voltage;
c) the nickel particles are fed into the nozzle at a feed rate of 1 g/min to 10 g/min, with 3.5 g/min being preferred;
d) the nickel particles are dispersed in the stream of carrier gas, this taking place before or after or during the ionization of the carrier gas;
e) the plasma flame leaves the nozzle in the direction of the thermoelectric active material;
f) the nozzle and the thermoelectric active material are moved in relation to one another, while maintaining the same distance, with an advancement of 80 mm/s to 250 mm/s, an advancement of 200 mm/s being preferred;
   in such a way
g) that the nickel particles fed to the nozzle are deposited on the thermoelectric active material by means of the plasma flame, and so the diffusion barrier grows on the thermoelectric active material with a layer thickness of 3 μm to 100 μm, a layer thickness of 10 μm to 20 μm being preferred.

If particles according to the invention are used, then in this way diffusion barriers of nickel of outstanding quality can be produced with a throughput that is appropriate for industrial mass production of thermoelectric components.

Thermoelectric active material such as bismuth telluride often has an oxide film that is produced on the semiconductor by contact with atmospheric oxygen. Such oxide films act as an electrical and thermal insulator, and so, in the interests of high energy efficiency of the thermoelectric component, these oxide films should be removed, at least in the region of the later diffusion barrier by way of which the electrical contact is established.

A particularly preferred embodiment of the invention envisages that, before the application of the diffusion barrier, the thermoelectric active material is treated in the region of the later diffusion barrier with a plasma flame in which no particles are dispersed, the plasma flame without dispersed particles being produced in a way analogous to the plasma flame with nickel particles dispersed in it, with the difference that no nickel particles are fed to the plasma flame without dispersed particles.

This development is based on the idea that the plasma flame that is used for the coating is also used for removing the oxide films before the coating. Used for this is a reducing carrier gas, such as hydrogen or forming gas, which reduces the oxide films. No particles are fed to the cleaning flame. Otherwise, the parameters of the coating installation can be retained. The same installation and work piece set-up device can thus be used for removing oxide films on the active material before the coating. This makes production particularly efficient. In comparison with cleaning with a blast of sand, using the plasma flame without adding particles has the advantage that the surface of the active material is not mechanically damaged as much.

The barrier layer is applied directly to the contact surface of the semiconductor (both of the n type and of the p type) freshly cleaned in the plasma jet—and consequently there is no risk of new contamination or new oxidation of the contact surface being caused by waiting times or interfaces in the installation. In order to avoid new oxidation, the process should be carried out under a protective atmosphere.

It can be seen as an advantage of the invention that a vacuum or positive pressure is not necessary. All that is needed is an enclosure, in order to achieve inertizing with the protective gas to avoid oxide formation, and also to prevent the release of finely divided metals into the surroundings.

It is also advantageous that it is possible to operate under atmospheric pressure. Accordingly, the method is for instance operated at atmospheric pressure, and so the absolute pressure of the protective atmosphere lies between 0.8*10⁵ Pa and 1.2*10⁵ Pa.

To ensure inertizing, and thereby avoid undesired oxide formation, the oxygen fraction in the protective atmosphere should be below 100 ppm % by volume. In particular, nitrogen with a purity of at least 99.9% by volume is used as the protective atmosphere.

An electrical contact bridge comprising an electrical conductor such as copper or aluminium is not generally soldered directly onto the diffusion barrier of nickel, but instead a contact maker layer is provided in between, improving the electrical contact of the solder on the nickel layer. According to the invention, the contact maker layer of tin is applied to the nickel barrier likewise with the aid of plasma spraying, preferably on the same installation. However, the tin powder to be processed for this is not chosen randomly, but rather has a mean sphericity SM of greater than 0.72. The ideal value is SM=0.77, and so the range around that of 0.75<SM<0.8 is particularly preferred. These values again relate to measurements with QicPic from the company Sympatec GmbH.

Since the use of a tin powder with a particular sphericity corresponds to the same concept of the invention as applies to the choice of the nickel powder, a method for producing a thermoleg for a thermoelectric component in which a contact maker layer consisting of tin is applied to a diffusion barrier of nickel with the aid of a plasma flame, and in which tin particles that conform to the specification mentioned with regard to their sphericity are fed to the plasma flame, is likewise the subject of the invention.

The contact maker layer need not necessarily be applied to a barrier layer plasma-sprayed according to the invention, but it makes perfect sense to carry out both process steps in the way according to the invention on the same installation.

In the plasma spraying with tin, the following parameters should be maintained:

Tin particles with a particle size distribution that conform to the following specification should be used:
D₅₀ from 1 μm to 40 μm, with 18 μm to 22 μm being preferred.

Tin powders with suitable sphericity and particle size distribution can be obtained by spray drying and screening.

The plasma flame for the tin spraying is a stream of an ionized carrier gas in which the tin particles are dispersed,
a) a carrier gas that is chosen from nitrogen, hydrogen or mixtures thereof being used, air being preferred as the carrier gas;
b) the carrier gas being ionized with the aid of an electrical voltage,
   in particular with a pulsed DC voltage of between 10 kV and 50 kV with a pulse frequency of between 15 kHz and 25 kHz;
c) the temperature of the plasma flame lying below 3000 K.

The plasma flame for the tin spraying is produced in a nozzle by
a) the carrier gas being fed into the nozzle with a volumetric flow of 10 Nl/min to 60 Nl/min, with 30 Nl/min being preferred;
b) the carrier gas being ionized in the nozzle by being passed through an electrical discharge induced by the electrical voltage;
c) the tin particles being fed into the nozzle at a feed rate of 1 g/min to 10 g/min, with 3.5 g/min being preferred;
d) the tin particles being dispersed in the stream of carrier gas, this taking place before or after or during the ionization of the carrier gas;
e) the plasma flame leaving the nozzle in the direction of the diffusion barrier;
f) and the nozzle and the diffusion barrier being moved in relation to one another, while maintaining the same distance, with an advancement of 80 mm/s to 250 mm/s, an advancement of 200 mm/s being preferred;
   in such a way
g) that the tin particles fed to the nozzle are deposited on the diffusion barrier by means of the plasma flame, and so the contact maker layer grows on the diffusion barrier with a layer thickness of 20 μm to 200 μm, a layer thickness of 50 μm to 100 μm being preferred.

Consequently, similar technological boundary conditions apply both to plasma coating with nickel and to plasma coating with tin, which underlies the unity of the invention.

Also decisive in both cases is the flowability of the particles, which makes corresponding feedability possible. The feeding of the nickel particles and the tin particles into the plasma flame takes place pneumatically. Powders with a sphericity according to the invention can consequently be continuously fed extremely well, even with the mass flows required on an industrial scale. The proportion of the volumetric flow for the pneumatic feeding is very low in comparison with the gas stream through the plasma.

Otherwise, it has been found with respect to the active material that during the coating the active material should be heated up to approximately 80° C., since this improves the growing on of the layer. A development of the invention consequently provides that the surface to be coated of the thermoelectric active material is set to a temperature of 60° C. to 100° C., in particular of 80° C., before the cleaning and/or before coating.

In principle, all of the thermoelectric active materials mentioned at the beginning can be coated by the technology according to the invention. However, tests show that bismuth tellurides can be coated particularly well, even when they are mixed with fractions of antimony and/or selenium.

Altogether, the process according to the invention aims for the following advantages:

The locally very limited energy input into the metal powders and into the surface passed over by the plasma flame of the workpiece to be coated reduces the heating up of the workpiece, and even allows the coating of temperature-sensitive materials, such as in particular many thermoelectric semiconductors or else thermoelectrically passive substrates that surround or enclose the thermolegs.

One particular advantage of the coating method according to the invention is that the reducing character of the plasma flame and the inertizing by the protective atmosphere avoid the formation of undesired metal oxides. This improves the adherence, reduces the resistance and consequently improves the efficiency of the thermoelectric module.

A further advantage of the method is that n and p legs can be metallized under the same conditions. A temperature adaptation on account of the different sintering temperatures of the two differently doped semiconductors is not necessary. This simplifies process management, and consequently costs.

Furthermore, the invention opens up the possibility of using just one processing station for three processing steps, both for the p-type leg and for the n-type leg. Suitable processing stations for atmospheric-pressure plasma spraying are available off-the-peg at low investment costs, are compact and can be automated well.

The invention advantageously allows the complete confinement of hazardous substances, that is the fine-powdered heavy metals nickel and tin. This is intrinsically obtained in the process by the necessary inert gas enclosure.

It is also an advantage of the invention that capacity adaptations are easily possible by arranging a number of identical stations in parallel.

Flexible structuring, i.e. rapid adaptation to specific requirements, is also possible by programmable 3D positioning of the spray heads and adjustability of the mass flow of metal. Small batches can also be implemented at low cost.

The metal layer applied according to the invention can be set to be highly porous to almost pore-free, depending on the plasma settings chosen and the metal powder fed in. It is possible by applying a sufficiently thick layer to produce a coating that is completely free from through-pores, and thus to protect the underlying structure completely from the action of fluids or to produce an effective diffusion barrier for the prevention of metal atom migration between the electrical conductor and the thermoelectric semiconductor.

The methods according to the invention for coating thermoelectric active material with nickel and tin lead to thermolegs with outstanding coating quality. Two thermolegs coated in such a way can be connected by soldering a contact bridge onto the coated locations to form a thermocouple that can be a component part of a thermoelectric component.

Since such a thermocouple benefits from the high coating quality achievable in the method according to the invention, a thermoelectric component comprising at least two thermolegs of thermoelectric active material that are connected in an electrically conducting manner by way of a contact bridge to form a thermocouple is likewise the subject of the invention if at least one of the thermolegs is obtainable or obtained by the according to the invention.

The invention will now be explained in more detail on the basis of figures. The figures show:

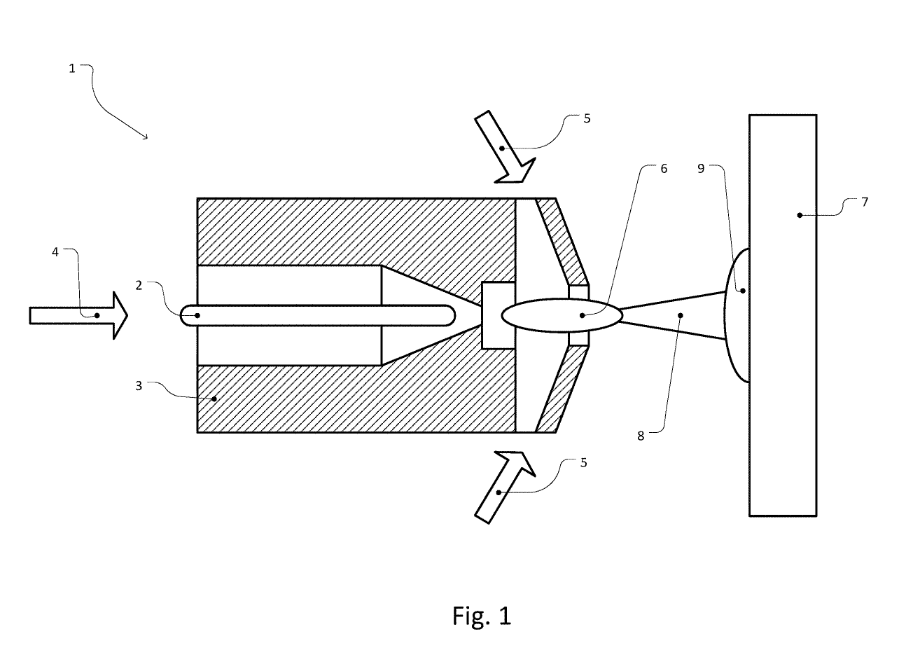

FIG. 1: a basic diagram;

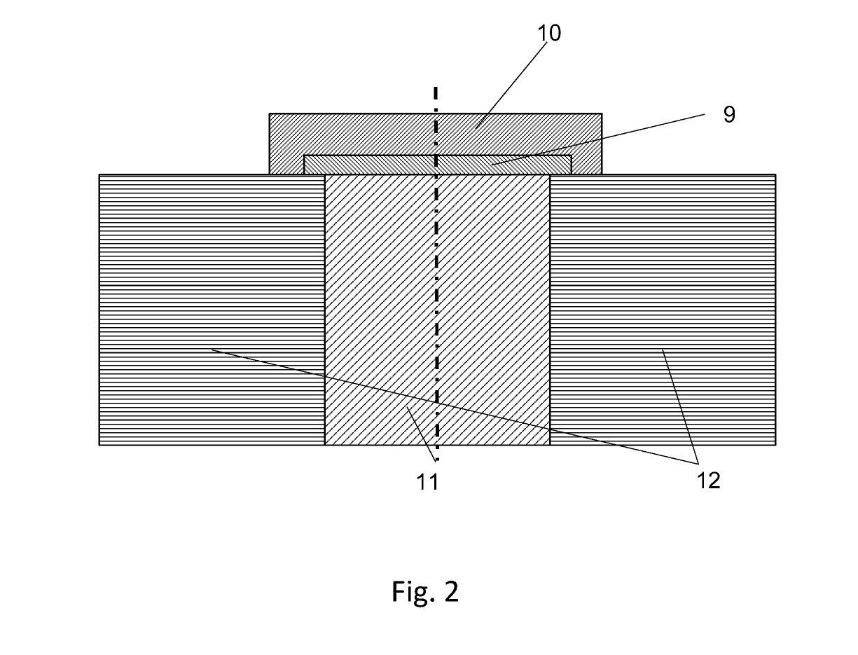

FIG. 2: a thermoleg of active material in a passive substrate with an Ni/Sb coating (first working result);

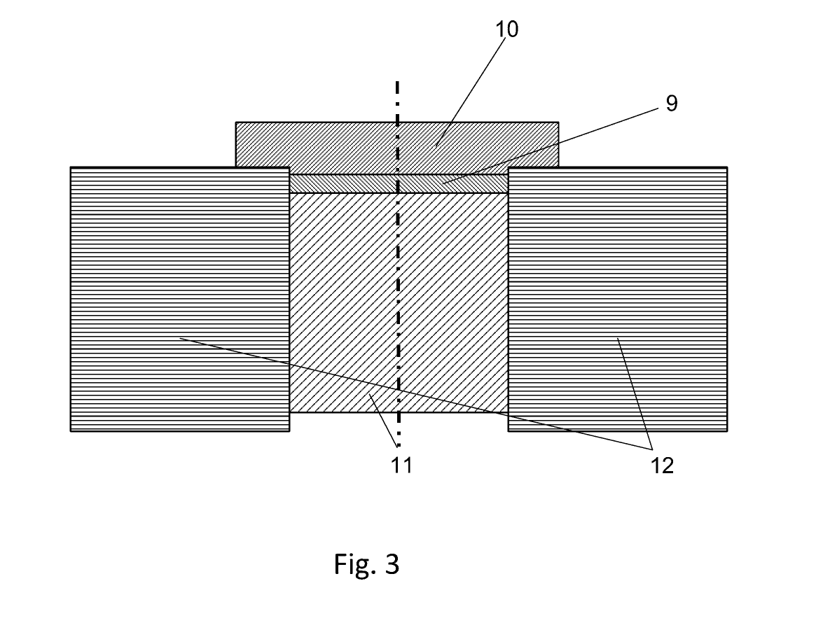

FIG. 3: a thermoleg of active material in a passive substrate with an Ni/Sb coating (second working result);

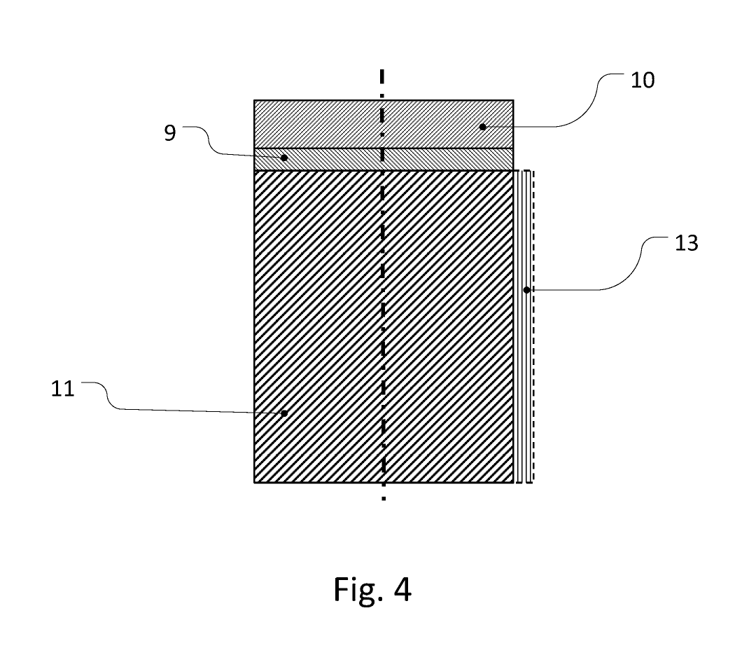

FIG. 4: a thermoleg of active material with an Ni/Sb coating (third working result);

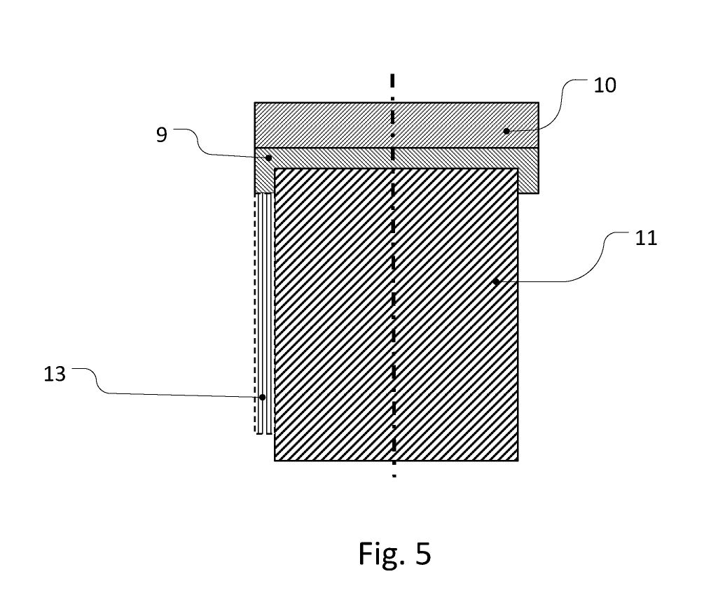

FIG. 5: a thermoleg of active material with an Ni/Sb coating (fourth working result).

FIG. 1 shows a basic diagram of the plasma spraying according to the invention. A nozzle 1 comprises a cathode 2 and an anode 3. The cathode 2 is arranged around the anode 3. A high voltage is applied between the cathode 2 and the anode 3. The high voltage is a pulsed DC voltage of 20 kV. The pulse frequency is 20 kHz. There is a spark discharge of the voltage between the anode 3 and the cathode 2.

A carrier gas 4 flows through the nozzle 1 and is ionized by the discharge of the high voltage between the anode and the cathode. In the region of the mouth of the nozzle 1, a metallic coating material 5 (nickel or tin) is introduced in the form of a powder. This takes place pneumatically with a non-ionized feed gas such as argon. In the nozzle 1, the powdered coating material 5 is dispersed in the carrier gas 4, and so a coating gas stream 6 emerges from the nozzle 1.

The nozzle is aligned with the thermoelectric active material 7 to be coated. As it approaches, the arc is ignited. By means of the plasma 8, the powdered coating material 5 is deposited on the surface to be coated of the thermoelectric active material 7. A manipulator that is not shown moves the active material 7 in relation to the fixed nozzle 1, and so a layer 9 of coating material grows on the surface of the active material. The relative movement takes place within a space filled with a protective atmosphere, to be more precise in an enclosure of the coating apparatus. Depending on the coating material 5 that is used (nickel or tin), the applied layer 9 is a diffusion barrier or a contact maker layer.

FIGS. 2 to 5 show various working results, in which a first layer 9 of nickel as a diffusion barrier and on it a second layer 10 of tin as a contact maker layer have been applied according to the invention to thermolegs 11 of thermoelectric active material. In the case of the working results shown in FIGS. 2 and 3, the thermoleg 11 is located in a thermoelectrically passive substrate 12 of a ceramic composite material. The thermolegs 11 in the case of the working results shown in FIGS. 4 and 5 are provided at their flanks, outside their electrical contact area, with an optional protective layer 13, which has likewise been applied according to the invention. Therefore, not only the electrical contact points of the active material can be coated according to the invention, but also other surface areas that are exposed to diffusion and oxidation.

### LIST OF REFERENCE NUMERALS

1 nozzle
2 cathode
3 anode
4 carrier gas
5 coating material (powdered)
6 coating gas stream
7 thermoelectric active material
8 plasma
9 first layer Ni (diffusion barrier)
10 second layer Sb (contact maker)
11 thermoleg
12 substrate
13 protective layer

1. A method for producing a thermoleg for a thermoelectric component, comprising:
applying a diffusion barrier of nickel to a thermoelectric active material with the aid of a plasma flame,
feeding nickel particles with a mean sphericity of greater than 0.74 to the plasma flame.

2. The method according to claim 1, wherein the nickel particles conform to the following specification with regard to their particle size distribution:
D₅₀ of 0.6 μm to 25 μm.

3. The method according to claim 2, wherein spray-dried and screened nickel particles are used.

4. The method according to claim 1, with the proviso that the plasma flame is a stream of an ionized carrier gas in which the nickel particles are dispersed,
wherein
a) a carrier gas is selected from the group consisting of nitrogen, hydrogen or mixtures thereof is used;
b) the carrier gas is ionized with the aid of an electrical voltage;
c) the temperature of the plasma flame lies below 3000 K.

5. The method according to claim 4, with the proviso that the plasma flame is produced in a nozzle, wherein
a) the carrier gas is fed into the nozzle with a volumetric flow of 10 Nl/min to 60 Nl/min;
b) the carrier gas is ionized in the nozzle by being passed through an electrical discharge induced by the electrical voltage;
c) the nickel particles are fed into the nozzle at a feed rate of 1 g/min to 10 g/min;
d) the nickel particles are dispersed in the stream of carrier gas, this taking place before or after or during the ionization of the carrier gas;
e) the plasma flame leaves the nozzle in the direction of the thermoelectric active material;
f) and the nozzle and the thermoelectric active material are moved in relation to one another, while maintaining the same distance, with an advancement of 80 mm/s to 250 mm/s;
in such a way
g) that the nickel particles fed to the nozzle are deposited on the thermoelectric active material by the plasma flame, and so the diffusion barrier grows on the thermoelectric active material with a layer thickness of 3 μm to 100 μm.

6. The method according to claim 1, wherein, before the application of the diffusion barrier, the thermoelectric active material is treated in the region of the later diffusion barrier with a plasma flame in which no particles are dispersed, the plasma flame without dispersed particles being produced in a way analogous to the plasma flame with nickel particles dispersed in it, with the difference that no nickel particles are fed to the plasma flame without dispersed particles.

7. The method according to claim 1, in which a contact maker layer is applied to a diffusion barrier of nickel with the aid of a plasma flame,
wherein the contact maker layer consists of tin, and tin particles with a mean sphericity of greater than 0.72 are fed to the plasma flame.

8. The method according to claim 7, wherein the tin particles conform to the following specification with regard to their particle size distribution:
D₅₀ of 1 μm to 40 μm.

9. The method according to claim 8, wherein spray-dried and screened tin particles are used.

10. The method according to claim 7, with the proviso that the plasma flame is a stream of an ionized carrier gas in which the tin particles are dispersed,
wherein
a) a carrier gas that is chosen from nitrogen, hydrogen or mixtures thereof is used;
b) the carrier gas is ionized with the aid of an electrical voltage;
c) the temperature of the plasma flame lies below 3000 K.

11. The method according to claim 10, with the proviso that the plasma flame is produced in a nozzle, wherein
a) the carrier gas is fed into the nozzle with a volumetric flow of 10 Nl/min to 60 Nl/min;
b) the carrier gas is ionized in the nozzle by being passed through an electrical discharge induced by the electrical voltage;
c) the tin particles are fed into the nozzle at a feed rate of 1 g/min to 10 g/min;
d) the tin particles are dispersed in the stream of carrier gas, this taking place before or after or during the ionization of the carrier gas;
e) the plasma flame leaves the nozzle in the direction of the diffusion barrier;
f) and the nozzle and the diffusion barrier are moved in relation to one another, while maintaining the same distance, with an advancement of 80 mm/s to 250 mm/s;
in such a way
g) that the tin particles fed to the nozzle are deposited on the diffusion barrier by the plasma flame, and so the contact maker layer grows on the diffusion barrier with a layer thickness of 20 μm to 200 μm.

12. The method according to claim 1, wherein the nickel particles and/or the tin particles are fed to the plasma flame with the aid of pneumatic feeding.

13. A thermoelectric component, comprising:
at least two thermolegs of thermoelectric active material that are connected in an electrically conducting manner by way of a contact bridge to form a thermocouple, at least one of the thermolegs being obtainable or obtained by a method according to claim 1.
